(19) United States
(12) Patent Application Publication
(10) Pub. No.: US 2025/0238585 A1
(43) Pub. Date: Jul. 24, 2025

(54) CONFIGURING DEFAULT FPGA APPLICATIONS ON NETWORK DEVICES WITH FPGA BASED DATA PLANES

(71) Applicant: Arista Networks, Inc., Santa Clara, CA (US)

(72) Inventors: Reid William Mayfield, Santa Cruz, CA (US); Gil Adrian Torres, San Francisco, CA (US)

(21) Appl. No.: 18/416,634

(22) Filed: Jan. 18, 2024

(51) Int. Cl. G06F 30/343

(52) U.S. Cl. CPC G06F 30/343

(57) ABSTRACT

Techniques for configuring a default FPGA application on a network device with an FPGA-based data plane (i.e., a data plane that is implemented using a FPGA) are provided. In one set of embodiments, the default FPGA application is loaded onto a non-volatile memory or storage component of the network device at the time of device manufacture and is automatically programmed into the FPGA during the device boot process if there is no user configuration specifying a user-selected FPGA application.

### BACKGROUND

Network devices such as switches and routers include a data plane, also known as a forwarding plane, that handles the processing and movement of network packets within/through the device (e.g., from an ingress port to an egress port) at line speed. In some network devices this data plane is implemented using a field-programmable gate array (FPGA), which is a type of integrated circuit that can be re-programmed with different applications, known as FPGA applications, to perform different tasks.

### BRIEF DESCRIPTION OF THE DRAWINGS

With respect to the discussion to follow and in particular to the drawings, it is stressed that the particulars shown represent examples for purposes of illustrative discussion and are presented in the cause of providing a description of principles and conceptual aspects of the present disclosure. In this regard, no attempt is made to show implementation details beyond what is needed for a fundamental understanding of the present disclosure. The discussion to follow, in conjunction with the drawings, makes apparent to those of skill in the art how embodiments in accordance with the present disclosure may be practiced. Similar or same reference numbers may be used to identify or otherwise refer to similar or same elements in the various drawings and supporting descriptions. In the accompanying drawings:

FIG. 1 depicts an example network device in accordance with certain embodiments of the present disclosure.

FIG. 2 depicts another version of the example network device of FIG. 1 in accordance with certain embodiments of the present disclosure.

FIG. 3 depicts a device manufacturing workflow in accordance with certain embodiments of the present disclosure.

FIG. 4 depicts a device boot workflow in accordance with certain embodiments of the present disclosure.

### DETAILED DESCRIPTION

In the following description, for purposes of explanation, numerous examples and details are set forth in order to provide an understanding of embodiments of the present disclosure. Particular embodiments as expressed in the claims may include some or all of the features in these examples, alone or in combination with other features described below, and may further include modifications and equivalents of the features and concepts described herein.

Embodiments of the present disclosure are directed to techniques for configuring a default FPGA application on a network device with an FPGA-based data plane (i.e., a data plane that is implemented using a FPGA). In one set of embodiments, this default FPGA application is loaded onto a non-volatile memory or storage component of the network device at the time of device manufacture and is automatically programmed into the FPGA during the device boot process if there is no user configuration specifying a user-selected FPGA application.

With these techniques, the network device can advantageously provide FPGA-based data plane capabilities “out-of-the-box” (i.e., upon first boot, without any user intervention), thereby streamlining its deployment and reducing the configuration burden of device users. For example, in a scenario where the network device is intended to typically operate as a Layer 2/3 switch, the default FPGA application may be a switch application that enables the device's FPGA to perform out-of-the-box Layer 2 and Layer 3 packet processing.

### 1. Example Network Device and Solution Overview

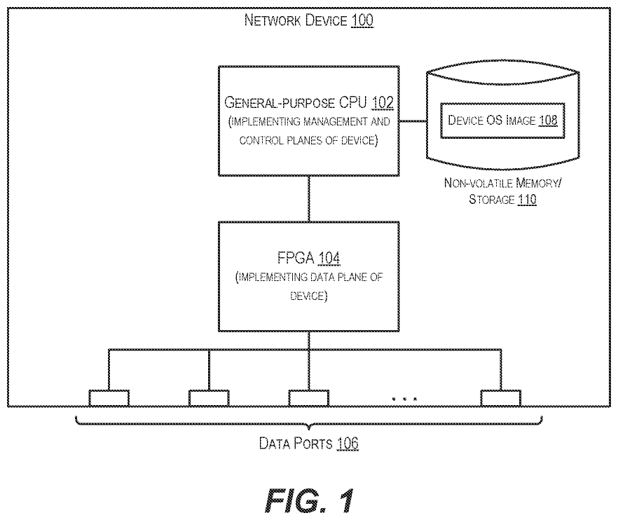

FIG. 1 is a simplified block diagram of an example network device 100 that may incorporate the techniques of the present disclosure. Network device 100 includes, among other things, a general-purpose central processing unit (CPU) 102 that is communicatively coupled with an FPGA 104. As mentioned previously, an FPGA is a type of integrated circuit that can be re-programmed with different FPGA applications to perform different tasks. This is in contrast to an application-specific integrated circuit (ASIC), which is a type of integrated circuit that is hardwired to perform a particular set of tasks. Network device 100 also includes a plurality of data ports 106 that are connected to FPGA 104 and are operable for receiving and transmitting network packets that enter and exit network device 100.

As shown in FIG. 1, CPU 102 implements the management and control planes of network device 100 and thus is generally responsible for (1) managing the configuration/operation of network device 100 and (2) controlling the device's understanding of the network in which it resides (e.g., determining routes/paths between network endpoints, discovering adjacent devices, etc.). CPU 102 carries out these management and control plane functions under the direction of a device operating system (OS) that runs on CPU 102 and is stored (in the form of a device OS image 108) on a non-volatile memory or storage 110. Non-volatile memory/storage 110 may comprise, e.g., one or more flash storage devices, one or more persistent or static memory devices, or the like.

FPGA 104 implements the data plane of network device 100 and thus is generally responsible for handling the processing and physical movement of network packets within/through network device 100 at line speed (i.e., the data throughput speed supported by the device), typically based on determinations made by the control plane. The specific nature of these data plane functions will differ depending on the intended functionality of network device 100. For example, in the case where network device 100 is intended to operate as a Layer 2 switch, the data plane may receive an inbound packet on an ingress port, extract the packet's Layer 2 (e.g., Ethernet) header, determine, based on the Layer 2 header and a forwarding information base (FIB) populated by the control plane, an egress port to which the packet should be sent in order to reach its intended destination, and forward the packet to the determined egress port. Alternatively, in the case where network device 100 is intended to operate as a Layer 1 switch, the data plane may receive an inbound packet on an ingress port and forward the packet to an egress port that is directly mapped to the ingress port.

One complication with deploying a network device with an FPGA-based data plane like network device 100 of FIG. 1 is that the device's FPGA should be programmed with an appropriate FPGA application (typically upon each device boot) in order for the FPGA to execute its intended data plane duties. Without such programming, the FPGA is effectively inoperable because the FPGA application defines how the FPGA's internal logic elements should be set/configured. This is not a problem for network devices with ASIC-based data planes because the internal logic of an ASIC is hardwired.

It is possible to overcome this issue by requiring the device user to manually configure an FPGA application on the network device (or in other words, specify, via one or more configuration commands, the FPGA application that the user wishes to have programmed into the FPGA) upon first boot of the device. The network device can then persist a reference to this user-selected FPGA application in, e.g., a user configuration file/data store and program the user-selected FPGA application into the FPGA on each subsequent boot. However, such manual configuration is burdensome for the device user and makes the network device less appealing to customers that expect the device to provide some level of data plane capabilities out-of-the-box. For example, if the network device is primarily marketed as a Layer 2/3 switch, customers may expect the network device to immediately work as such without any user configuration or intervention.

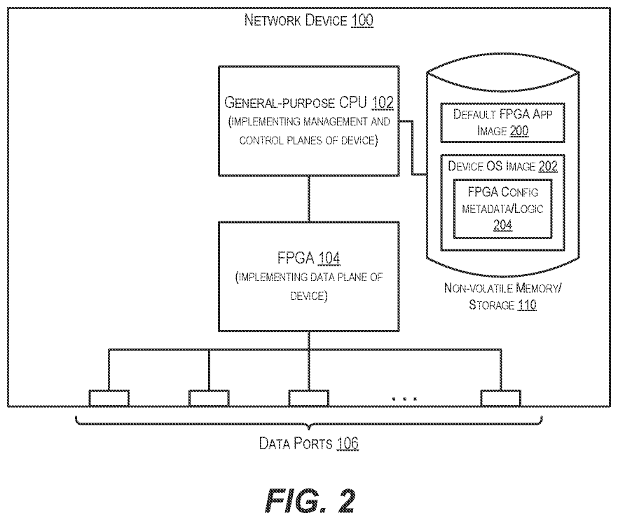

To address the foregoing, embodiments of the present disclosure provide a novel framework for configuring a default (i.e., manufacturer-selected) FPGA application on a network device with an FPGA-based data plane like network device 100. In one set of embodiments, this framework involves loading, onto non-volatile memory/storage 110 at the time of manufacture of network device 100, an image (i.e., packaged representation) of the default FPGA application and an image of the device OS that has been modified/enhanced to include a new FPGA configuration metadata/logic component. The default FPGA application is an FPGA application that has been pre-selected by the device manufacturer for programming into FPGA 104 in order to provide data plane capabilities for network device 100. The FPGA configuration metadata/logic included in the modified device OS image comprises data and/or program code that allows, among other things, the device OS to recognize the default FPGA application image loaded onto non-volatile memory/storage 110 as being the manufacturer-selected default. By way of example, FIG. 2 depicts a version of network device 100 that shows these images (a default FPGA application image 200 and a device OS image 202 with FPGA configuration metadata/logic 204) stored on non-volatile memory/storage 110.

Then, at the time of device boot, network device 100—or more precisely, the OS of network device 100, in accordance with its FPGA configuration metadata/logic 204—can identify image 200 in non-volatile memory/storage 110 as corresponding to the default FPGA application for device 100 and can configure itself accordingly. For example, the device OS can populate one or more configuration settings indicating that image 200 is an image of the default FPGA application. The device OS can further check whether a user-selected FPGA application, or an image thereof, has been specified in a user configuration of device 100. This user configuration can be, e.g., a file or some other data store comprising device configuration information created/defined by a device user. If the answer is no, the device OS can proceed with programming image 200 into FPGA 104. If the answer is yes, the device OS can retrieve and program the user-selected FPGA application image into FPGA 104 in accordance with the user configuration.

With the general framework above, a number of benefits are realized. First, because the default FPGA application is pre-configured by the device manufacturer and automatically programmed into FPGA 104 upon device boot (assuming there is no user-configured alternative), FPGA 104 is ready to perform the data plane functions supported by the default FPGA application out-of-the-box, thereby expediting the process of deploying network device 100 and reducing the amount of manual configuration performed by device users. This is particularly useful if many instances of network device 100 need to be deployed together in a large environment such as a data center and/or if device 100 is expected, from a marketing/sales perspective, to provide such out-of-the-box capabilities. For example, in the scenario mentioned previously where network device 100 is primarily marketed as a Layer 2/3 switch, the default FPGA application may be a switch application that enables FPGA 104 to perform out-of-the-box Layer 2 switching and Layer 3 routing. In other scenarios, the default FPGA application may support other types of data plane functions (e.g., Layer 1 switching, Layer 4-7 load balancing, etc.).

Second, even with this framework in place, the users of network device 100 retain the flexibility to configure an alternative, user-selected FPGA application on the device at any point in time. For example, once network device 100 has booted up and programmed default FPGA application image 200 into FPGA 104, a user can invoke one or more configuration commands on device 100 for specifying a user-selected FPGA application image and persisting this information in the device's user configuration. In certain embodiments, this will cause network device 100 to program the user-selected FPGA application image, in lieu of default FPGA application image 200, into FPGA 104 on the next (and all subsequent) boots. Similarly, the user can revert back to the default FPGA application at any point by removing the specification of the user-selected FPGA application image from the user configuration.

It should be appreciated that FIGS. 1 and 2 are illustrative and not intended to limit embodiments of the present disclosure. For example, although the data plane of network device 100 is shown as being implemented using a single FPGA, in some embodiments the data plane may be implemented using multiple FPGAs, each connected to a different subset of data ports and connected to each other via a data fabric/backplane. In these embodiments, the default FPGA application may be automatically programmed into all such FPGAs.

Further, in some embodiments the data plane of network device 100 may be implemented using one or more non-FPGA components, in addition to FPGA 104. For example, the data plane may be implemented using a combination of FPGA 104 and an ASIC or a hardware crosspoint. In these embodiments, the default FPGA application may enable FPGA 104 to perform data plane functions that extend or complement the data plane capabilities provided by the non-FPGA components.

### 2. Device Manufacturing Workflow

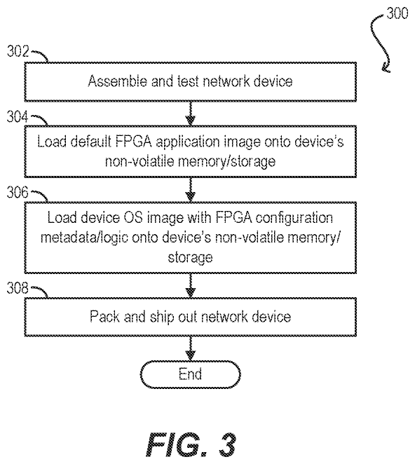

FIG. 3 depicts a device manufacturing workflow 300 that may be performed by the manufacturer of network device 100 according to certain embodiments, which includes loading default FPGA application image 200 and modified device OS image 202 (with FPGA configuration metadata/logic 204) onto the device. In particular, workflow 300 may be performed by a human user and/or automated agent that is associated with the device manufacturer. The end result of this workflow is the version of network device 100 shown in FIG. 2.

Starting with block 302, the device manufacturer can assemble and test network device 100.

At block 304, the device manufacturer can load default FPGA application image 200 onto non-volatile memory/storage 110 of network device 100. As mentioned previously, image 200 is a packaged representation (e.g., in a binary format) of a default FPGA application that has been selected by the device manufacturer for programming into the device's FPGA 104, in the absence of user configuration specifying an alternative FPGA application.

At block 306, the device manufacturer can load device OS image 202 onto non-volatile memory/storage 110 of network device 100, which includes FPGA configuration metadata/logic 204. FPGA configuration metadata/logic 204 includes information and/or program code that specifies default FPGA application image 200 as corresponding to the default, or manufacturer-selected, FPGA application for network device 100. In certain embodiments, FPGA configuration metadata/logic 204 may also specify additional configuration parameters pertaining to default FPGA application image 200. For instance, if the default FPGA application embodied in image 200 supports multiple operating modes or profiles, FPGA configuration metadata/logic 204 may specify a default operating mode/profile for the application upon being programmed into FPGA 104.

As a particular example, assume the default FPGA application is a Layer 2/3 switch application that supports a low latency profile (which offers low switching/routing latency but relatively few features) and a full feature profile (which offers a larger set of features at the expense of higher switching/routing latency). In this example, FPGA configuration metadata/logic 204 may specify either the low latency profile or the full feature profile as the default profile for the application.

Finally, once images 200 and 202 have been loaded onto network device 100, the device manufacturer can pack and ship the device to a customer/user (or to a retail channel for sale to a customer/user) (block 308).

### 3. Device Boot Workflow

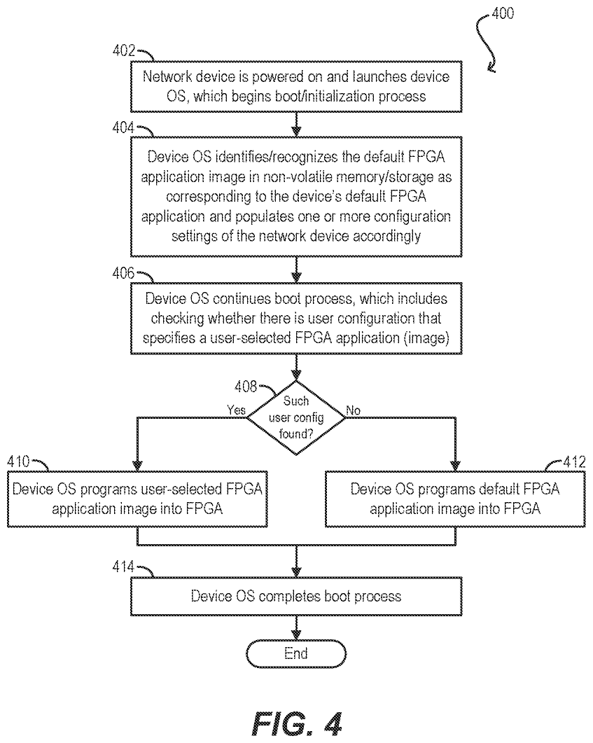

FIG. 4 depicts a device boot workflow 400 that may be performed by network device 100 according to certain embodiments. Workflow 400 assumes that network device 100 has been manufactured per device manufacturing workflow 300 of FIG. 3.

Starting with block 402, network device 100 is powered on and launches the device OS from image 202 stored in non-volatile memory/storage 110, which causes the device OS to begin its boot/initialization process.

At block 404, in accordance with FPGA configuration metadata/logic 204, the device OS can identify/recognize default FPGA application image 200 stored in non-volatile memory/storage 110 as being an image of the default FPGA application for network device 100 and can populate one or more configuration settings of the device to indicate this. For example, in one set of embodiments the device OS may populate a “default FPGA application” configuration setting of network device 100 with a name, identifier (ID), and/or storage path of default FPGA application image 200. For example, if the name of default FPGA application image 200 is “switchapp.swix” and the image is stored under the directory “/mnt/flash”, this configuration setting may be populated with the string “/mnt/flash/switchapp.swix.” In alternative embodiments, the device OS may populate this configuration setting with a name and/or ID of the default FPGA application embodied by image 200 (e.g., “switch application”).

In cases where FPGA configuration metadata/logic 204 also includes other configuration parameters pertaining to the default FPGA application (e.g., a default operating mode/profile), the device OS can also populate the device's configuration settings with these additional parameters. For example, if default FPGA application image 200 supports low latency/full feature profiles and FPGA configuration metadata/logic 204 indicates that the low latency profile should be the default, the device OS may populate a “default FPGA application profile” configuration setting of network device 100 with an identifier of the low latency profile.

At block 406, the device OS can continue its boot process, which can include checking whether network device 100 has any user configuration that specifies a user-selected FPGA application (and/or an image thereof). If such user configuration is found at block 408, the device OS can retrieve the user-selected FPGA application image and can program it into FPGA 104 (block 410).

However, if no such user configuration is found at block 408, the device OS can retrieve default FPGA application image 200 (as defined in the configuration setting(s) populated at block 404) and can program image 200 into FPGA 104 (block 412). This programming step can take into account any additional parameters included in the configuration setting(s), such as a default operating mode or profile for the default FPGA application.

Finally, at block 414, the device OS can complete the boot process and workflow 400 can end. At this point, network device 100/FPGA 104 will be ready to perform the data plane functions supported by the default FPGA application.

It should be noted that while workflow 400 assumes the device OS will program either the default FPGA application image or a user-selected FPGA application image into FPGA 104, in certain embodiments the device OS may program both of these images if FPGA 104 supports this functionality and if the two images do not conflict with each other. In this way, FPGA 104 can be programmed to provide the data plane functions supported by the default FPGA application as well as additional data plane functions supported by the user-selected FPGA application.

### 4. Storing the Default FPGA Application in FPGA Configuration Memory

The framework described in the foregoing sections is particularly suited for network devices with static RAM (SRAM) based FPGAs because such FPGAs typically do not have any internal non-volatile memory for persisting their programmed FPGA applications across power cycles. Accordingly, SRAM-based FPGAs need to be re-programmed upon each device boot, which is the approach shown in workflow 400 of FIG. 4.

However, some FPGAs do include internal non-volatile (e.g., flash) memory, which is sometimes referred to as configuration memory. For network devices with these types of FPGAs, an alternative approach for configuring a default FPGA application on the device involves storing, at the time of device manufacture, the default FPGA application image directly in the FPGA's internal configuration memory (rather than, or in addition to, loading the image onto the device's non-volatile memory/storage). This will cause the FPGA to automatically program itself with the contents of the configuration memory (and thus, with the default FPGA application image) upon being powered on, without intervention by the device OS.

In these embodiments, a device user can still configure a different, user-selected FPGA application on the network device by, e.g., entering one or more configuration commands. In response to such commands, the user-selected FPGA application image will be persisted to the FPGA configuration memory, overwriting the default FPGA application image. In some embodiments, the network device may still be shipped with a copy of the default FPGA application image on its non-volatile memory/storage, in addition to being stored in FPGA configuration memory. This will allow the default FPGA application image to be re-written to the FPGA configuration memory at a later time if needed (e.g., in a scenario where the device user wishes to revert from a user-selected FPGA application to the default FPGA application).

The above description illustrates various embodiments of the present disclosure along with examples of how aspects of these embodiments may be implemented. The above examples and embodiments should not be deemed to be the only embodiments and are presented to illustrate the flexibility and advantages of the present disclosure as defined by the following claims. For example, although certain embodiments have been described with respect to particular workflows and steps, it should be apparent to those skilled in the art that the scope of the present disclosure is not strictly limited to the described workflows and steps. Steps described as sequential may be executed in parallel, order of steps may be varied, and steps may be modified, combined, added, or omitted. As another example, although certain embodiments may have been described using a particular combination of hardware and software, it should be recognized that other combinations of hardware and software are possible, and that specific operations described as being implemented in hardware can also be implemented in software and vice versa.

The specification and drawings are, accordingly, to be regarded in an illustrative rather than restrictive sense. Other arrangements, embodiments, implementations, and equivalents will be evident to those skilled in the art and may be employed without departing from the spirit and scope of the present disclosure as set forth in the following claims.

1. A method performed by a network device upon boot, the network device including a field-programmable gate array (FPGA) for performing data plane functions, the method comprising:
identifying a default FPGA application image stored in a non-volatile memory or storage component of the network device as being an image of a default FPGA application that has been selected by a manufacturer of the device, wherein the default FPGA application image was loaded onto the non-volatile memory or storage component at a time of device manufacture, and wherein the default FPGA application is an FPGA application that enables Layer 2 and/or Layer 3 packet processing;
determining whether a user-selected FPGA application is specified in a user configuration of the network device; and
upon determining that a user-selected FPGA application is not specified in the user configuration, programming the default FPGA application image into the FPGA.

2. The method of claim 1 further comprising, upon determining that a user-selected FPGA application is specified in the user configuration:
programming an image of the user-selected FPGA application into the FPGA.

3. The method of claim 1 further comprising, upon determining that a user-selected FPGA application has been specified in the user configuration:
programming the default FPGA application image and an image of the user-selected FPGA application into the FPGA.

4. The method of claim 1 further comprising, subsequently to programming the default FPGA application image into the FPGA:
receiving input from a user selecting another FPGA application different from the default FPGA application; and
updating the user configuration to include a reference to said another FPGA application, thereby causing the network device to program said another FPGA application into the FPGA when the network device is next booted.

5. The method of claim 1 wherein the identifying, determining, and programming are performed in accordance with an FPGA configuration metadata or logic component included in a device operating system (OS) image stored in the non-volatile memory or storage component.

6. The method of claim 1 wherein the programming of the default FPGA application image into the FPGA takes into account one or more configuration parameters associated with the default FPGA application that are included in a device OS image stored in the non-volatile memory or storage component.

7. The method of claim 6 wherein the one or more configuration parameters specify a default operating mode or profile for the default FPGA application.

8. A network device comprising:
a central processing unit (CPU);
a field-programming gate array (FPGA) implementing a data plane of the network device; and
a non-volatile memory or storage component having stored thereon:
a default FPGA application image corresponding to a default FPGA application that has been selected by a manufacturer of the device for programming into the FPGA; and
an image of a device operating system (OS) including an FPGA configuration metadata or logic component,
wherein the default FPGA application image and the image of the device OS were loaded onto the non-volatile memory or storage component at a time of device manufacture,
wherein the default FPGA application is an FPGA application that, upon being programmed into the FPGA, enables the FPGA to perform Layer 2 and/or Layer 3 packet processing, and
wherein the FPGA configuration metadata or logic component of the device OS causes the CPU to automatically program the default FPGA application image into the FPGA upon boot up of the network device, in the absence of user configuration specifying a user-selected FPGA application.

9. The network device of claim 8 wherein the data plane of the network device is implemented solely using the FPGA.

10. The network device of claim 8 wherein the data plane of the network device is implemented using the FPGA and one or more other non-FPGA components.

11. The network device of claim 10 wherein the one or more other non-FPGA components includes an application-specific integrated circuit (ASIC) or a crosspoint.

12. The network device of claim 10 wherein the one or more other non-FPGA components provide one or more data plane functions that are different from data plane functions enabled by the default FPGA application.

13. The network device of claim 8 wherein, upon detecting a user-selected FPGA application in the user configuration, the FPGA configuration metadata or logic component of the device OS causes the CPU to automatically program an image of the user-selected FPGA application into the FPGA in lieu of the default FPGA application image.

14. The network device of claim 8 wherein the user-selected FPGA application supports one or more data plane functions that are different from the default FPGA application.

15. A method performed by a network device upon boot, the network device including a field-programmable gate array (FPGA) for performing data plane functions, the method comprising:
identifying a default FPGA application image stored in a non-volatile memory or storage component of the network device as being an image of a default FPGA application that has been selected by a manufacturer of the device;
determining whether a user-selected FPGA application is specified in a user configuration of the network device; and
upon determining that a user-selected FPGA application is not specified in the user configuration, programming the default FPGA application image into the FPGA.

16. The method of claim 15 wherein the default FPGA application image was loaded onto the non-volatile memory or storage component at a time of device manufacture.

17. The method of claim 15 wherein the default FPGA application is an FPGA application that enables Layer 2 and/or Layer 3 packet processing.

18. The method of claim 15 wherein the default FPGA application is an FPGA application that enables Layer 1 switching.

19. The method of claim 15 wherein the default FPGA application is an FPGA application that enables Layer 4 through Layer 7 load balancing.

20. The method of claim 15 wherein the method enables the network device to perform data plane functions supported by the default FPGA application upon first boot, without requiring a device user to perform any configuration of the network device.
